(19) United States
(12) Patent Application Publication
(10) Pub. No.: US 2002/0167005 A1
(43) Pub. Date: Nov. 14, 2002

(54) Semiconductor structure including low-leakage, high crystalline dielectric materials and methods of forming same

(75) Inventors: Zhiyi Yu, Gilbert, AZ (US); Ravindranath Droopad, Chandler, AZ (US); Corey Overgaard, Phoenix, AZ (US)

Correspondence Address: OBLON, SPIVAK, McCLELLAND, MAIER & NEUSTADT, P.C., FOURTH FLOOR, 1755 JEFFERSON DAVIS HIGHWAY, ARLINGTON, VA, 22202, US

(73) Assignee: Motorola, Inc

(21) Appl. No.: 09/853,744

(22) Filed: May 11, 2001

(51) Int. Cl. H01L 29/12; H01L 21/84; H01L 31/0392

(52) U.S. Cl. 257/43; 438/85; 438/86; 438/104; 438/754; 257/347; 257/352; 438/149

(57) ABSTRACT

The present invention provides semiconductor structures and methods for forming semiconductor structures which include monocrystalline oxide films exhibiting both high dielectric constants and low leakage current densities. In accordance with various aspects of the invention, a semiconductor structure includes a monocrystalline semiconductor substrate and one or more stoichiometrically graduated monocrystalline oxide layers. The stoichiometrically graduated monocrystalline oxide layer may include a perovskite material, such as an alkaline-earth metal titanate. Semiconductor devices fabricated in accordance with aspects of the present invention exhibit a high dielectric constant as well as a reduced leakage current density.

### FIELD OF THE INVENTION

The present invention relates generally to semiconductor structures and devices and to methods for their fabrication and, more specifically, to semiconductor structures and devices and to the fabrication and use of semiconductor structures, devices, and integrated circuits that include high dielectric constant, epitaxial oxide films formed by varying the flux ratio of the elemental components of the oxide during deposition to achieve reduced leakage current density without sacrificing high crystalline quality.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

Epitaxial growth of single-crystal oxide thin films on single-crystal silicon substrates is therefore of great value in numerous device applications, such as ferroelectric devices, non-volatile high density memory devices, and next-generation metal oxide semiconductor (MOS) devices, for example. Preparation of these films generally requires the formation of an ordered transition layer or buffer layer on the surface of the silicon substrate to facilitate subsequent growth of the single-crystal oxide layer.

Certain monocrystalline oxides, such as BaO and BaTiO₃, have been formed on <100>oriented silicon substrates using a BaSi₂ (cubic) template by depositing one fourth of a monolayer of barium on the silicon substrate using molecular beam epitaxy (MBE) at temperatures greater than 850° C. See, e.g., R. McKee et al., Appl. Phys. Lett. 59(7), pp. 782-784 (Aug. 12, 1991); R. McKee et al., Appl. Phys. Lett. 63(20), pp. 2818-2820 (Nov. 15, 1993); R. McKee et al., Mat. Res. Soc. Symp. Proc., Vol. 21, pp. 131-135 (1991); U.S. Pat. No. 5,225,031, issued Jul. 6, 1993, entitled “Process For Depositing An Oxide Epitaxially Onto A Silicon Substrate And Structures Prepared With The Process”; and U.S. Pat. No. 5,482,003, issued Jan. 9, 1996, entitled “Process For Depositing Epitaxial Alkaline Earth Oxide Onto A Substrate And Structures Prepared With The Process.” A strontium silicide (SrSi₂) interface model with a c(4×2) structure also has been proposed. See, e.g., R. McKee et al., Phys. Rev. Lett. 81(14), 3024 (Oct. 5, 1998). However, atomic-level simulation of this proposed structure suggests that it likely is not stable at elevated temperatures.

Growth of SrTiO₃ on <100>oriented silicon substrates using an SrO buffer layer also has been achieved. See, e.g., T. Tambo et al., Jpn. J. Appl. Phys., Vol. 37, pp. 4454-4459 (1998). However, the SrO buffer layer was comparatively thick (100 Å), thereby rendering its application unsuitable for transistor films, and crystallinity was not maintained throughout the growth of the SrTiO₃ film.

Additionally, SrTiO₃ has been grown on silicon using thick (60-120 Å) oxide layers of SrO or TiO. See, e.g., B. K. Moon et al., Jpn. J. Appl. Phys., Vol. 33, pp. 1472-1477 (1994). As previously noted, however, thick buffer layers are generally not well-suited for MOS transistor applications.

In gate dielectric applications, high dielectric constant (high-k) films exhibiting low leakage current densities and high crystallinity are highly desirable. However, the inherent tension between these desired electrical and physical characteristics imposes limitations on the suitability of such films for the fabrication of high-quality MOS transistors. For example, while the leakage current density of SrTiO₃ films on a silicon substrate decreases as the Sr/Ti ratio increases above unity, the crystal structure of such films typically degrades as the Sr/Ti ratio increases above unity. In other words, stoichiometric SrTiO₃ films (i.e., films where Sr/Ti=1), which generally exhibit a favorably high degree of crystallinity, tend to demonstrate an unfavorably high leakage current density. Thus, since both leakage current density and crystallinity tend to vary in inverse proportion to the stoichiometric ratio of the elemental components of the oxide film, the development of structures and methods which effectively harmonize these competing physical and electrical properties would be highly advantageous for the fabrication of superior semiconductor devices and integrated circuitry.

It has been suggested that reduced leakage current density in oxide films can be achieved by incorporating foreign dopants, such as silicon in the form of SiO₂ into TiO₂, or by introducing silver into (Ba,Sr)TiO₃ films. However, structures formed by such methods are problematic because they involve foreign elements, such as silver, and tend to exhibit elemental diffusion and/or segregation which adversely affect devices fabricated by these methodologies.

Accordingly, a need exists for semiconductor structures and devices and methods of fabricating semiconductor structures and devices which overcome the shortcomings of the prior art. Thus, there is a need for semiconductor structures and devices including high-k oxide films exhibiting both high crystallinity and low leakage current density. Moreover, a need exists for a method of fabricating epitaxial perovskite films on single-crystal substrates to achieve both low leakage current density and high crystallinity.

### BRIEF DESCRIPTION OF THE DRAWINGS

The present invention is illustrated by way of example, and not of limitation in the accompanying figures, in which like references indicate similar elements, and in which:

FIGS. 1A-1B illustrate schematically, in cross section, a semiconductor device structure fabricated in accordance with one embodiment of the present invention;

FIGS. 2A-2B illustrate schematically, in cross section, a semiconductor device structure fabricated in accordance with an alternative embodiment of the present invention;

FIGS. 3A-3B illustrate schematically, in cross section, a semiconductor device structure fabricated in accordance with yet a further embodiment of the present invention;

FIGS. 4A-4B illustrate schematically, in cross section, a semiconductor device structure fabricated in accordance with another embodiment of the present invention; and

FIG. 5 illustrates adjustment of the flux ratio of the elemental components of an oxide film during deposition of the film in accordance with one embodiment of the present invention.

FIG. 6 illustrates adjustment of the flux ratio of the elemental components of an oxide film during deposition of the film in accordance with an alternative embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

The following disclosure presents and describes various exemplary embodiments in sufficient detail to enable those skilled in the art to practice the invention, and it should be understood that other embodiments may be realized without departing from the spirit and scope of the invention. Thus, the following detailed description is presented for purposes of illustration only, and not of limitation, and the scope of the invention is defined solely by the appended claims.

Preliminarily, as used herein, the term “perovskite” is intended to comprise, but not be limited to, compounds or materials exhibiting a general crystal structure of stoichiometry (A,B)MO₃, where A is an alkali metal or alkaline-earth metal; B is optional and, if present, is an alkali metal or alkaline-earth metal; M is at least one transition metal; and O is oxygen. Moreover, the term “perovskite” also is intended to comprise, but not be limited to, non-stoichiometric crystalline compounds or materials exhibiting a crystal structure of the general form (A_{z}B_{1-z})₁₊ₓMO₃₊ₓ (where x is greater than 0 and z ranges from 0 to 1), where A is an alkali metal or alkaline-earth metal; B is optional and, if present, is an alkali metal or alkaline-earth metal; M is at least one transition metal; and O is oxygen. It also should be understood that while particular perovskite materials (such as alkaline-earth metal titanates, zirconates, hafnates, tantalates, vanadates, ruthenates, and niobates; lanthanum aluminates; and lanthanum scandium oxides for example) may be used to illustrate various aspects and embodiments of the present invention, these examples are illustrative only and are not intended to be restrictive. Additionally, as used herein, the terms “deposition flux ratio” and “flux ratio” are synonymous and are intended to mean the ratio of the respective flux rates of each of the elemental components of a monocrystalline oxide which is formed or grown on an underlying substrate or material layer. Further, as used herein, the phrase “stoichiometrically graduated” is intended to mean having incrementally different ratios, or relative quantities, of the elemental components of a material or oxide layer, such that the layer exhibits a range or spectrum of relative quantities of those elemental components throughout the various monolayers comprising the material or oxide layer.

An exemplary process for fabricating a semiconductor structure exhibiting a low leakage current density and high crystallinity begins by providing a monocrystalline layer, such as a monocrystalline material layer overlying a substrate or another material layer or a monocrystalline semiconductor substrate comprising, for example, silicon and/or germanium. In accordance with one embodiment of the invention, a semiconductor substrate comprising a silicon wafer having a <100>orientation provides a suitable monocrystalline layer. The substrate may be oriented on axis or about 2°-6° off axis. At least a portion of the semiconductor substrate has a bare surface, although other portions of the substrate, as described below, may encompass other structures. The term “bare” in this context means that the portion of the substrate surface has been cleaned to remove any oxides, contaminants, or other foreign materials. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention.

Epitaxial growth of a monocrystalline oxide layer overlying a monocrystalline substrate is facilitated by first removing the native oxide layer to expose the crystalline structure of the underlying substrate. An exemplary process is generally carried out by molecular beam epitaxy (MBE), although other processes, such as those outlined below, may also be used in accordance with the present invention. The native oxide can be removed by first thermally depositing a thin layer of strontium, barium, a combination of strontium and barium, or other alkaline-earth metals or combinations of alkaline-earth metals in an MBE apparatus. In the case where strontium is used, the substrate is either initially kept at a lower temperature (e.g., room temperature to about 700° C.) during the alkaline-earth metal deposition and then heated to a higher temperature of about 750° C. or maintained at a higher temperature (e.g., about 700-800° C.) throughout the deposition process (such as under ultra-high vacuum chemical vapor deposition (UHVCVD) for example) to cause the strontium to react with the native silicon oxide layer. The strontium serves to reduce the native silicon oxide and leaves a silicon oxide-free surface. The resultant surface may exhibit an ordered 2×1 structure. If an ordered 2×1 structure has not been achieved at this stage in the process, the structure may be exposed to additional strontium until an ordered 2×1 structure is obtained. The ordered 2×1 structure forms a template for the epitaxial growth of an overlying layer of a monocrystalline oxide. The template provides favorable chemical and physical properties to nucleate the crystalline growth of an overlying layer.

In accordance with an alternate embodiment of the invention, the native silicon oxide can be reduced, and the substrate surface can be prepared for the growth of a monocrystalline oxide layer by depositing an alkaline earth oxide, such as strontium oxide, strontium barium oxide, or barium oxide, onto the substrate surface by MBE at a low temperature and by subsequently heating the structure to a temperature of about 750° C. under reduced oxygen partial pressure. At this temperature, a solid state reaction takes place between the strontium oxide and the native silicon oxide, causing the reduction of the native silicon oxide and creating an ordered 2×1 structure.

Following the removal of the silicon oxide from the surface of the substrate, in accordance with one embodiment of the invention, the substrate is cooled b a temperature in the range of about 200-800° C., and a monocrystalline oxide layer, such as a perovskite layer comprising strontium titanate for example, is grown on the template layer by MBE. The MBE process is initiated by opening shutters in the MBE apparatus to expose sources of the appropriate elements, such as strontium, titanium, and oxygen sources in the case of growing strontium titanate. The ratio of the alkali metal or alkaline-earth metal to the transition metal is substantially stoichiometric. For example, in the case of strontium titanate, the ratio of strontium to titanium is about 1:1. The partial pressure of oxygen is initially set at a minimum value, such as a value in the range of about (1-5)×10⁻⁷ mBar, to grow a stoichiometric monocrystalline oxide layer. In the case of strontium titanate, the growth rate is about 0.2-0.5 nm per minute. After initiating growth of the monocrystalline oxide layer, the partial pressure of oxygen is increased above the initial minimum value to a value in the range of about (0.5-5)×10⁻⁶ mBar.

The process described above illustrates a process for forming a semiconductor structure including a silicon substrate and an overlying oxide layer by the process of molecular beam epitaxy. The process can also be carried out by the process of chemical vapor deposition (CVD), metal organic chemical vapor deposition (MOCVD), ultra-high vacuum chemical vapor deposition (UHVCVD), migration enhanced epitaxy (MEE), atomic layer epitaxy (ALE), physical vapor deposition (PVD), chemical solution deposition (CSD), laser MBE, pulsed laser deposition (PLD), and/or the like. Moreover, by similar processes, other monocrystalline oxide materials, such as other perovskites including alkali metal or alkaline-earth metal titanates, zirconates, hafnates, tantalates, vanadates, ruthenates, and niobates as well as oxides of the lanthanide series elements, such as lanthanum aluminates and lanthanum scandium oxides, can also be grown.

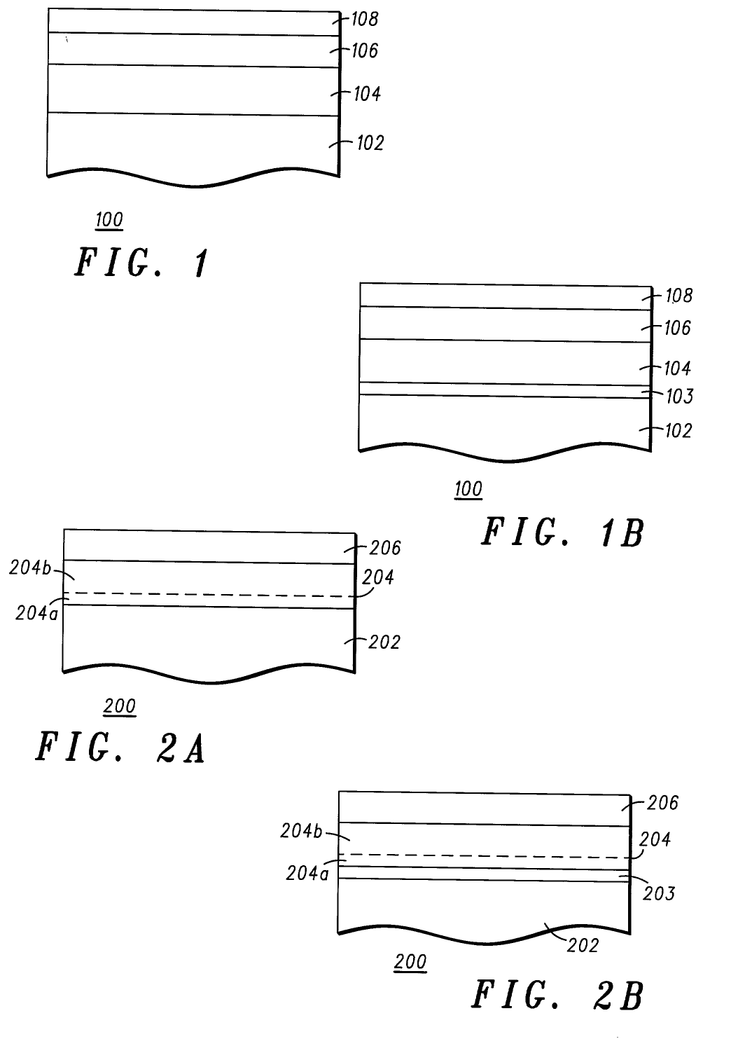

FIG. 1A illustrates schematically, in cross section, a structure 100 in accordance with one embodiment of the present invention. Structure 100 may be, for example, a gate dielectric component for an MOS device or any high-k device. Structure 100 includes a monocrystalline semiconductor substrate 102. Substrate 102 may comprise any suitable monocrystalline semiconductor material or compound semiconductor material, including silicon (Si), germanium (Ge), silicon germanium (SiGe), silicon carbide (SiC), indium phosphide (InP), gallium arsenide (GaAs), indium gallium arsenide (InGaAs), indium aluminum arsenide (InAlAs), aluminum gallium arsenide (AlGaAs), and indium gallium phosphide (InGaP). Preferably, substrate 102 comprises a monocrystalline silicon wafer.

A monocrystalline oxide layer 104 is formed overlying substrate 102. In one embodiment, monocrystalline oxide layer 104 is a monocrystalline oxide material selected for its crystalline compatibility with both the underlying substrate and the overlying semiconductor material or compound semiconductor material. In this embodiment, layer 104 may comprise, for example, a substantially stoichiometric perovskite, such as an alkaline-earth metal titanate like barium titanate (BaTiO₃), strontium titanate (SrTiO₃), or barium strontium titanate (Sr_{z}Ba_{1-z}TiO₃, where z ranges from 0 to 1). A stoichiometric alkaline-earth metal titanate is achieved where the ratio of alkaline-earth metal to titanium is about 1:1. In one embodiment, layer 104 is a layer of substantially stoichiometric SrTiO₃ having a thickness of about 2-10 monolayers and preferably a thickness of about 3-5 monolayers.

With momentary reference to FIG. 1B, in accordance with an alternative embodiment of the invention, structure 100 may also include an amorphous interfacial layer 103 which is grown on substrate 102 at the interface between substrate 102 and the growing oxide layer 104 by the oxidation of substrate 102 during the growth of layer 104. The amorphous interfacial layer 103 may serve to relieve strain that might otherwise occur in the monocrystalline oxide layer as a result of differences in the lattice constants of the substrate and the oxide layer. If such strain is not relieved by the amorphous interfacial layer 103, the strain may cause defects in the crystalline structure of the oxide layer. Defects in the crystalline structure of the monocrystalline oxide layer, in turn, might compromise the crystalline quality of additional monocrystalline oxide layer 106. Amorphous interfacial layer 103 is preferably an oxide formed by the oxidation of the surface of substrate 102 and, more preferably, is composed of a silicon oxide. The thickness of layer 103 is sufficient to relieve strain attributed to mismatches between the lattice constants of substrate 102 and monocrystalline oxide layer 104. Typically, layer 103 has a thickness in the range of approximately 0.3-2 nm and preferably has a thickness in the range of about 0.5-0.7 nm.

Referring once again to FIG. 1A, an additional monocrystalline oxide layer 106 is formed overlying layer 104. In one embodiment, monocrystalline oxide layer 106 is a monocrystalline oxide material selected for its crystalline compatibility with layer 104. In this embodiment, layer 106 may comprise, for example, a non-stoichiometric perovskite, such as non-stoichiometric barium titanate, strontium titanate, or barium strontium titanate. A non-stoichiometric perovskite layer is achieved where the ratio of alkali metal or alkaline-earth metal to the transition metal is greater than about 1 and may be achieved by establishing different flux rates for the alkali metal or alkaline earth metal and the transition metal during formation of the perovskite layer. For example, in the case of an alkaline-earth metal titanate, if the flux rate for the alkaline-earth metal is greater than the flux rate for the titanium, a non-stoichiometric alkaline-earth metal titanate is formed with a ratio of alkaline-earth metal to titanium greater than 1. Preferably, the ratio of alkaline-earth metal to titanium is less than or equal to about 2. In one embodiment, layer 106 is a layer of non-stoichiometric SrTiO₃ which can have a thickness of about 10-30 monolayers and preferably has a thickness of about 25 monolayers. The combined equivalent oxide thickness of layers 104 and 106 is less than or equal to about 15 nm and is preferably about 10-15 nm.

In another embodiment, monocrystalline oxide layer 106 may comprise a graduated, non-stoichiometric perovskite, such as a graduated, non-stoichiometric barium titanate, strontium titanate, or barium strontium titanate for example. In this embodiment, layer 106 is formed by incrementally adjusting the flux ratio (i.e., the ratio of the respective flux rates) of the alkali metal or alkaline-earth metal to the transition metal during deposition of layer 106. For example, a gradual increase or ramping of the flux ratio from a first non-stoichiometric ratio at the start of epitaxy to a second non-stoichiometric ratio at the end of epitaxy permits the formation of a stoichiometrically graduated monocrystalline oxide layer having high crystallinity and reduced leakage current density. In one embodiment, the flux ratio of the alkali metal or alkaline-earth metal to the transition metal is gradually increased from about 1 to about 2 over the course of the deposition of layer 106 over layer 104. In one aspect of this embodiment, layer 106 comprises a graduated, non-stoichiometric oxide thickness of about 10-15 nm.

In an alternative embodiment, layer 106 is formed by incrementally adjusting the flux ratio of the alkali metal or alkaline-earth metal to the transition metal during deposition of layer 106 such that the flux ratio is gradually increased from a first non-stoichiometric ratio at the start of epitaxy to a second non-stoichiometric ratio, and then the flux ratio is gradually decreased to a stoichiometric ratio again by the end of epitaxy. In one embodiment, the flux ratio of the alkali metal or alkaline-earth metal to the transition metal is gradually increased from about 1 to about 2 and then back down to about 1 over the course of the deposition of layer 106 over layer 104. In one aspect of this embodiment, layer 106 comprises an oxide of variable stoichiometry having a thickness of about 10-15 nm.

In accordance with one embodiment of the invention, a monocrystalline layer 108 may be formed overlying layer 106. Layer 108 may comprise any suitable monocrystalline semiconductor material or compound semiconductor material, including silicon (Si), germanium (Ge), silicon germanium (SiGe), silicon carbide (SiC), indium phosphide (InP), gallium arsenide (GaAs), indium gallium arsenide (InGaAs), indium aluminum arsenide (InAlAs), aluminum gallium arsenide (AlGaAs), and indium gallium phosphide (InGaP). In one embodiment, layer 108 can have a thickness of about 5-500 nm and preferably has a thickness of about 200 nm.

In another embodiment, layers 104 and 106 may collectively comprise a gate dielectric for a high dielectric constant semiconductor device, such as an MOS device. A conductive gate electrode (not shown), rather than layer 108, may be formed on layer 106 to complete the device structure in accordance with techniques well known to those skilled in the art. Processing may then continue in accordance with standard techniques to form a substantially complete integrated circuit incorporating a device structure of the present invention.

FIG. 2A illustrates schematically, in cross section, a semiconductor device structure 200 in accordance with another embodiment of the present invention. Device structure 200 may be a device such as, for example, an MOS device or any high-k device. Structure 200 includes a monocrystalline material layer, such as monocrystalline semiconductor substrate 202 which is preferably a monocrystalline silicon wafer.

A monocrystalline oxide layer 204 is formed overlying substrate 202. Monocrystalline oxide layer 204 is preferably a monocrystalline oxide material selected for its crystalline compatibility with both the underlying substrate and the overlying semiconductor material or compound semiconductor material. Layer 204 may comprise, for example, a perovskite film deposited on the substrate 202 using any suitable deposition process, such as MBE for example. In this embodiment, layer 204 is formed by incrementally adjusting the deposition flux ratio of the alkali metal or alkaline-earth metal to the transition metal during deposition of layer 204. For example, epitaxy may begin with a material exhibiting a general crystal structure of stoichiometry (A,B)MO₃, as described in greater detail above, and, over the course of the deposition process, may end with a material exhibiting a crystal structure of the general form (A_{z}B_{1-z})₁₊ₓMO₃₊ₓ (where x is greater than 0 and z ranges from 0 to 1), as described in greater detail above. This stoichiometrically graduated deposition of the oxide film creates a high degree of ordering at the start of epitaxy, which assists in maintaining surface smoothness and crystallinity of the layer, and also produces advantageous insulative properties as the flux ratio is increased over the course of epitaxy.

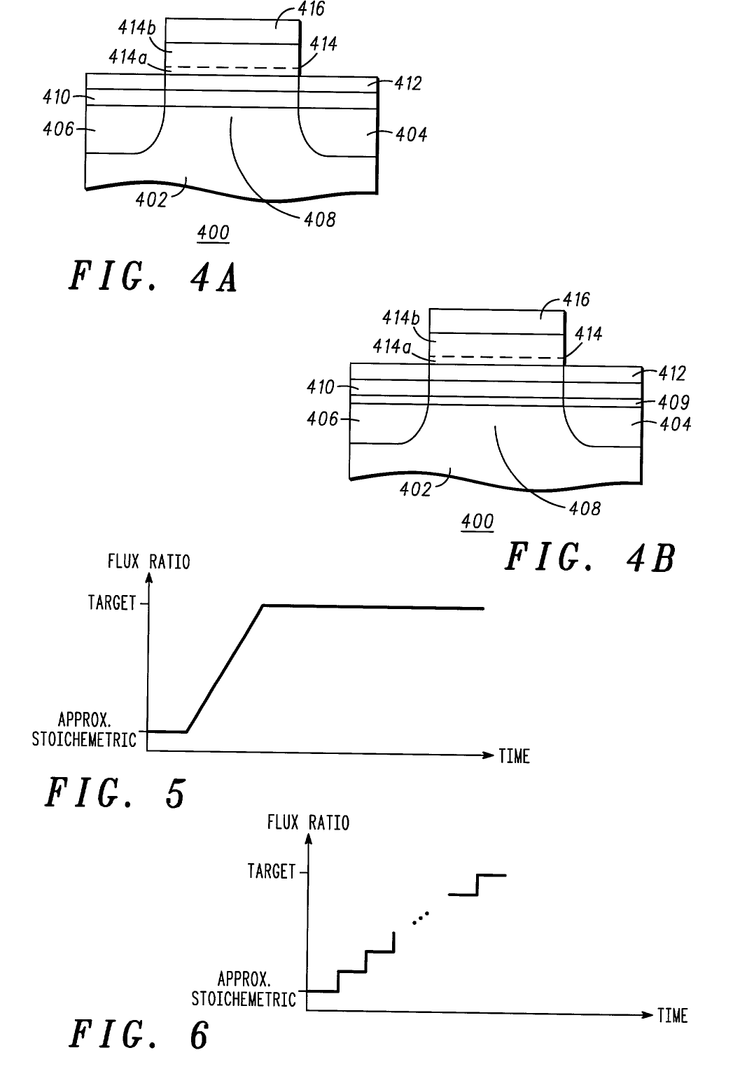

As generally illustrated in FIG. 5, gradually increasing or ramping the flux ratio from a substantially stoichiometric ratio at the start of epitaxy to a target non-stoichiometric ratio at the end of epitaxy permits the formation of a stoichiometrically graduated oxide layer, which enables manipulation of the electrical properties (i.e., resistivity and conductivity) of the resultant device as well as formation of a monocrystalline oxide film exhibiting low leakage current density, high crystalline quality, and suitable surface smoothness. It should be understood that FIG. 5 is not drawn to scale and is intended as a general, non-quantitative illustration of aspects of the invention. Thus, FIG. 5 is not intended to represent relative quantities, relative rates, relative periods of time, or any other variable or non-variable data which may otherwise be derived from such an illustration.

In one embodiment, the flux ratio of the alkali metal or alkaline-earth metal to the transition metal is gradually increased from about stoichiometric (i.e., about 1) to about 2 over the course of the deposition of layer 204 over substrate 202. The rate of increase of the flux ratio is about 3% per minute to about 20% per minute and preferably about 10% per minute. In this embodiment, layer 204 comprises a region 204a of about 2-5 monolayers of substantially stoichiometric perovskite material and a region 204b of about 10-50 monolayers of graduated, non-stoichiometric perovskite material. It should be understood that the dashed line separating regions 204a and 204b in FIG. 2A has been inserted merely for clarity and convenience of reference and is not intended to denote that regions 204a and 204b are distinct layers of structure 200, nor is it intended to indicate the relative thicknesses of regions 204a and 204b. Preferably, layer 204 comprises a region 204a of about 34 monolayers of substantially stoichiometric perovskite material and a region 204b of about 25-30 ionolayers of graduated, non-stoichiometric perovskite material. In one aspect of this embodiment, layer 204 comprises a graduated, substantially stoichiometric to non-stoichiometric oxide having a thickness of less than or equal to about 15 nm and preferably about 10-15 nm.

In an exemplary embodiment, layer 204 comprises any suitable perovskite material, such as an alkaline-earth metal titanate, hafnate, zirconate, tantalate, vanadate, ruthenate, niobate, and/or the like. For example, in the case of barium titanate, epitaxy may begin with a substantially stoichiometric Ba/Ti flux ratio (i.e., about 1:1), which is gradually increased or ramped-up to an ending flux ratio of about 2:1, forming a region of graduated, non-stoichiometric Ba₁₊ₓTiO₃₊ₓ (where x is greater than 0) within monocrystalline oxide layer 204. In this embodiment, oxide growth by MBE is conducted at temperatures ranging from about 200 to about 800° C., and preferably from about 400 to about 600° C. The partial pressure of oxygen is initially set at a minimum value, such as a value in the range of about (1-5)×10⁻⁷ mBar. The growth rate of the oxide layer is about 0.2-0.5 nm per minute. After initiating growth of the monocrystalline oxide layer, the partial pressure of oxygen is increased above the initial minimum value to a value in the range of about (0.5-5)×10⁻⁶ mBar. Similarly, in further exemplary embodiments, substantially stoichiometric strontium titanate may be ramped-up from a Sr/Ti ratio of about 1:1 to form a region of graduated, non-stoichiometric Sr₁₊ₓTiO₃₊ₓ (where x is greater than 0), and substantially stoichiometric barium strontium titanate may be ramped-up from a (Sr_{z}Ba_{1-z})/Ti ratio of about 1:1 to form a region of graduated, non-stoichiometric (Sr_{z}Ba₁₋₁)₁₊ₓTiO₃₊ₓ (where x is greater than 0 and z ranges from 0 to 1).

In another embodiment, layer 204 may be formed by incrementally increasing the deposition flux ratio of the alkali metal or alkaline-earth metal to the transition metal during deposition of layer 204 and then incrementally decreasing the deposition flux ratio. For example, epitaxy may begin with a material exhibiting a general crystal structure of stoichiometry (A,B)MO₃, may continue with a material exhibiting a crystal structure of the general form (A_{z}B_{1-z})₁₊ₓMO₃₊ₓ (where x is greater than 0 and z ranges from 0 to 1), and then end with a material exhibiting a general crystal structure of stoichiometry (A,B)MO₃. In this embodiment, the flux ratio of the alkali metal or alkaline-earth metal to the transition metal is gradually increased from about stoichiometric (i.e., about 1) to about 2 and then back down to about 1 over the course of the deposition of layer 204 over substrate 202. The rate of increase of the flux ratio is about 3% per minute to about 20% per minute and preferably about 10% per minute. The rate of decrease of the flux ratio is about 3% per minute to about 20% per minute and preferably about 10% per minute. In this embodiment, layer 204 comprises about 3-4 monolayers of substantially stoichiometric perovskite material underlying about 25-30 monolayers of graduated, non-stoichiometric perovskite material, which underlies about 3-4 monolayers of substantially stoichiometric perovskite material. In one aspect of this embodiment, layer 204 exhibits a graduated, substantially parabolic stoichiometry achieved by the sequential deposition of substantially stoichiometric oxide monolayers followed by non-stoichiometric oxide monolayers and then by substantially stoichiometric oxide monolayers to ultimately form an oxide layer having a thickness of about 10-15 nm.

For example, in the case of barium titanate, epitaxy may begin with a substantially stoichiometric Ba/Ti flux ratio (i.e., about 1:1). This ratio is then gradually increased or ramped-up to a flux ratio of about 2:1, forming a region of graduated, non-stoichiometric Ba₁₊ₓTiO₃₊ₓ (where x is greater than 0) within monocrystalline oxide layer 204. Epitaxy then continues with the Ba/Ti flux ratio being gradually decreased to an ending substantially stoichiometric flux ratio (i.e., about 1:1). The flux ratio of any suitable perovskite, as described above, may be similarly manipulated such that layer 204 exhibits a substantially parabolic stoichiometry. Oxide growth is accomplished by any suitable means or process, as described above.

With momentary reference to FIG. 2B, in accordance with an alternative embodiment of the invention, structure 200 may also include an amorphous interfacial layer 203 which is grown on substrate 202 at the interface between substrate 202 and the growing oxide layer 204 by the oxidation of substrate 202 during the growth of layer 204. The amorphous interfacial layer 203 may serve to relieve strain that might otherwise occur in the monocrystalline oxide layer as a result of differences in the lattice constants of the substrate and the oxide layer. If such strain is not relieved by the amorphous interfacial layer 203, the strain may cause defects in the crystalline structure of the oxide layer. Defects in the crystalline structure of the monocrystalline oxide layer, in turn, might compromise the crystalline quality of monocrystalline material layer 206. Amorphous interfacial layer 203 is preferably an oxide formed by the oxidation of the surface of substrate 202 and, more preferably, is composed of a silicon oxide. The thickness of layer 203 is sufficient to relieve strain attributed to mismatches between the lattice constants of substrate 202 and monocrystalline oxide layer 204. Typically, layer 203 has a thickness in the range of approximately 0.3-2 nm and preferably has a thickness in the range of about 0.5-0.7 nm.

In accordance with another embodiment of the invention, a monocrystalline material layer 206 is formed overlying layer 204. Layer 206 may comprise any suitable monocrystalline semiconductor material or compound semiconductor material, including silicon (Si), germanium (Ge), silicon germanium (SiGe), silicon carbide (SiC), indium phosphide (InP), gallium arsenide (GaAs), indium gallium arsenide (InGaAs), indium aluminum arsenide (InAlAs), aluminum gallium arsenide (AlGaAs), and indium gallium phosphide (InGaP). In one embodiment, layer 206 can have a thickness of about 5-500 nm and preferably has a thickness of about 200 nm.

Alternatively, in another embodiment, structure 200 may comprise a gate dielectric for a high-k semiconductor device, such as an MOS device. In this embodiment, a conductive gate electrode (not shown), rather than layer 206, may be formed on layer 204 to complete the device structure in accordance with techniques well known to those skilled in the art. Processing may then continue in accordance with standard techniques to form a substantially complete integrated circuit incorporating a device structure of the present invention.

FIG. 3A illustrates schematically, in cross section, a semiconductor device structure 300 fabricated in accordance with one alternative embodiment of the present invention, wherein semiconductor device structure 300 comprises an MOS device. Structure 300 includes a monocrystalline semiconductor substrate 302, preferably a monocrystalline silicon wafer. Drain region 304 and source region 306 are formed in substrate 302 using techniques well known to those skilled in the art, such as, for example, ion implantation of at least one dopant. Suitable dopants may include boron, aluminum, gallium, indium, phosphorus, arsenic, and antimony. A channel region 308 is defined by drain region 304 and source region 306 and comprises the portion of substrate 302 between regions 304 and 306.

A monocrystalline oxide layer 310 is formed overlying substrate 302 within channel region 308. In one embodiment, substrate 302 comprises a monocrystalline layer of compound semiconductor material, such as gallium arsenide, indium gallium arsenide, indium aluminum arsenide, aluminum gallium arsenide, or indium gallium phosphide, which overlies a bulk monocrystalline substrate, such as silicon, germanium, silicon germanium, gallium arsenide, indium phosphide, or silicon carbide. Layer 310 is preferably a monocrystalline oxide material selected for its crystalline compatibility with both the underlying substrate 302 and any overlying semiconductor material or compound semiconductor material. In this embodiment, layer 310 may comprise, for example, a perovskite film deposited on the substrate 302 using any suitable deposition process, such as MBE for example. Layer 310 may be formed by incrementally adjusting the flux ratio (i.e., the ratio of the respective flux rates) of the alkali metal or alkaline-earth metal to the transition metal during deposition of layer 310, as described in greater detail above with reference to layer 204 of FIG. 2A. For example, epitaxy may begin with a material exhibiting a general crystal structure of stoichiometry (A,B)MO₃, and, over the course of the deposition process, may end with a material exhibiting a crystal structure of the general form (A_{z}B_{1-z})₁₊ₓMO₃₊ₓ (where x is greater than 0 and z ranges from 0 to 1). Alternatively, epitaxy may begin with a material exhibiting a general crystal structure of stoichiometry (A,B)MO₃, may continue with a material exhibiting a crystal structure of the general form (A_{z}B_{1-z})₁₊ₓMO₃₊ₓ (where x is greater than 0 and z ranges from 0 to 1), and then end with a material exhibiting a general crystal structure of stoichiometry (A,B)MO₃.

In one embodiment, the flux ratio of the alkali metal or alkaline-earth metal to the transition metal is gradually increased from about stoichiometric (i.e., about 1:1) to about 2:1 over the course of the deposition of layer 310 over substrate 302. The rate of increase of the flux ratio is about 3% per minute to about 30% per minute and preferably about 10% per minute. In this embodiment, layer 310 comprises a region 310a of about 2-5 monolayers of substantially stoichiometric perovskite material and a region 310b of about 10-50 monolayers of graduated, non-stoichiometric perovskite material. It should be understood that the dashed line separating regions 310a and 310b in FIG. 3A has been inserted merely for clarity and convenience and is not intended to denote that regions 310a and 310b are distinct layers of structure 300, nor is it intended to indicate the relative thicknesses of regions 310a and 310b. Preferably, layer 310 comprises a region 310a of about 3-4 monolayers of substantially stoichiometric perovskite material and a region 310b of about 25-30 monolayers of graduated, non-stoichiometric perovskite material. In one aspect of this embodiment, layer 310 comprises a graduated, substantially stoichiometric to non-stoichiometric oxide having a thickness of less than or equal to about 15 nm and preferably about 10-15 nm.

In an exemplary embodiment, layer 310 comprises any suitable perovskite material, such as an alkaline-earth metal titanate, hafnate, zirconate, tantalate, vanadate, ruthenate, niobate, and/or the like. For example, in the case of barium titanate, epitaxy may begin with a substantially stoichiometric Ba/Ti flux ratio (i.e., about 1:1), which is gradually increased or ramped-up to an ending flux ratio of about 2:1 forming a region of graduated, non-stoichiometric Ba₁₊ₓTiO₃₊ₓ (where x is greater than 0) within monocrystalline oxide layer 310. In this embodiment, oxide growth by MBE is conducted at temperatures ranging from about 200 to about 800° C., and preferably about 400 to about 600° C. The partial pressure of oxygen is initially set at a minimum value, such as a value in the range of about (1-5)×10⁻⁶ mBar. The growth rate of the oxide layer is about 0.2-0.5 nm per minute. After initiating growth of the monocrystalline oxide layer, the partial pressure of oxygen is increased above the initial minimum value to a value in the range of about (0.5-5)×10⁻⁶ mBar. Similarly, in further exemplary embodiments, substantially stoichiometric strontium titanate may be ramped-up from about 1:1 to form a region of graduated, non-stoichiometric Sr₁₊ₓTiO₃₊ₓ (where x is greater than 0), and substantially stoichiometric barium strontium titanate may be ramped-up from about 1:1 to form a region of graduated, non-stoichiometric (Sr_{z}Ba_{1-z})₁₊ₓTiO₃₊ₓ, (where x is greater than 0 and z ranges from 0 to 1). A conductive gate electrode 312 may then be formed on layer 310 in accordance with techniques well known to those skilled in the art to complete the structure of the MOS device.

In one embodiment of the present invention, layer 310 exhibits a substantially parabolic stoichiometry, as described above in greater detail with reference to layer 204 of FIG. 2A. In this embodiment, layer 310 is formed by varying the deposition flux ratio of the alkali metal or alkaline-earth metal to the transition metal from a substantially stoichiometric ratio to a non-stoichiometric ratio and then back down to a substantially stoichiometric flux ratio. This varied stoichiometry is advantageous in that it reduces the leakage current of the oxide layer without sacrificing high crystallinity.

As seen in FIG. 3B, in accordance with an alternative embodiment of the invention, structure 300 may also include an amorphous interfacial layer 309 which is grown on substrate 302 at the interface between substrate 302 and the growing oxide layer 310 by the oxidation of substrate 302 during the growth of layer 310. The amorphous interfacial layer 309 may serve to relieve strain that might otherwise occur in the monocrystalline oxide layer as a result of differences in the lattice constants of the substrate and the oxide layer. If such strain is not relieved by the amorphous interfacial layer 309, the strain may cause defects in the crystalline structure of the oxide layer. Amorphous interfacial layer 309 is preferably an oxide formed by the oxidation of the surface of substrate 302 and, more preferably, is composed of a silicon oxide. The thickness of layer 309 is sufficient to relieve strain attributed to mismatches between the lattice constants of substrate 302 and monocrystalline oxide layer 310. Typically, layer 309 has a thickness in the range of approximately 0.3-2 nm and preferably has a thickness of about 0.5-0.7 nm.

FIG. 4A illustrates schematically, in cross section, a semiconductor device structure 400 fabricated in accordance with a further embodiment of the present invention, wherein semiconductor device structure 400 comprises an MOS device. Structure 400 includes a monocrystalline semiconductor substrate 402, preferably a monocrystalline silicon wafer. Drain region 404 and source region 406 are formed in substrate 402 using techniques well known to those skilled in the art, such as, for example, ion implantation of at least one dopant. Suitable dopants may include boron, aluminum, gallium, indium, phosphorus, arsenic, and antimony. A channel region 408 is defined by drain region 404 and source region 406 as a portion of substrate 402 between regions 404 and 406.

A monocrystalline oxide layer 410 is formed overlying substrate 402. In one embodiment, substrate 402 comprises a monocrystalline layer of compound semiconductor material, such as gallium arsenide, indium gallium arsenide, indium aluminum arsenide, aluminum gallium arsenide, or indium gallium phosphide, which overlies a bulk monocrystalline substrate, such as silicon, germanium, silicon germanium, gallium arsenide, indium phosphide, or silicon carbide. In one embodiment, layer 410 is a monocrystalline oxide material selected for its crystalline compatibility with both the underlying substrate 402 and an overlying semiconductor material or compound semiconductor material layer 412. In this embodiment, layer 410 may comprise a perovskite, such as an alkaline-earth metal titanate, hafnate, zirconate, tantalate, vanadate, ruthenate, niobate, or the like. In an exemplary embodiment, layer 410 is a layer of (Ba,Sr)TiO₃ having a thickness of about 2-10 monolayers.

In accordance with an alternative embodiment, as seen in FIG. 4B, structure 400 may also include an amorphous interfacial layer 409 which is grown on substrate 402 at the interface between substrate 402 and the growing oxide layer 410 by the oxidation of substrate 402 during the growth of layer 410. The amorphous interfacial layer 409 may serve to relieve strain that might otherwise occur in the monocrystalline oxide layer as a result of differences in the lattice constants of the substrate and the oxide layer. If such strain is not relieved by the amorphous interfacial layer 409, the strain may cause defects in the crystalline structure of the oxide layer. Defects in the crystalline structure of the monocrystalline oxide layer, in turn, might compromise the crystalline quality of semiconductor material layer 412. Amorphous interfacial layer 409 is preferably an oxide formed by the oxidation of the surface of substrate 402 and, more preferably, is composed of a silicon oxide. The thickness of layer 409 is sufficient to relieve strain attributed to mismatches between the lattice constants of substrate 402 and monocrystalline oxide layer 410. Typically, layer 409 has a thickness in the range of approximately 0.3-2 nm and preferably has a thickness in the range of about 0.5-0.7 nm.

Referring once again to FIG. 4A, compound semiconductor layer 412, which is formed overlying layer 410, may comprise, for example, silicon germanium (SiGe), silicon carbide (SiC), indium phosphide (InP), gallium arsenide (GaAs), indium gallium arsenide (InGaAs), indium aluminum arsenide (InAlAs), aluminum gallium arsenide (AlGaAs), or indium gallium phosphide (InGaP). A monocrystalline oxide layer 414 is then formed overlying layer 412 and channel region 408. Layer 414 is preferably a monocrystalline oxide material selected for its crystalline compatibility with layer 412. In the illustrated embodiment, layer 414 may comprise a perovskite layer formed by incrementally adjusting the flux ratio (i.e., the ratio of the respective flux rates) of the alkali metal or alkaline-earth metal to the transition metal during deposition of layer 414, as further described above. For example, epitaxy may begin with a material exhibiting a general crystal structure of stoichiometry (A,B)MO₃ and, over the course of the deposition process, may end with a material exhibiting a crystal structure of the general form (A_{z}B_{1-z})₁₊ₓMO₃₊₁ (where x is greater than 0 and z ranges from 0 to 1). Alternatively, epitaxy may begin with a material exhibiting a general crystal structure of stoichiometry (A,B)MO₃, may continue with a material exhibiting a crystal structure of the general form (A_{z}B_{1-z})₁₊ₓMO₃₊ₓ (where x is greater than 0 and z ranges from 0 to 1), and then end with a material exhibiting a general crystal structure of stoichiometry (A,B)MO₃.

In one embodiment, the flux ratio of the alkali metal or alkaline-earth metal to the transition metal is gradually increased from about stoichiometric (i.e., about 1:1) to about 2:1 over the course of the deposition of layer 414 over layer 412. The rate of increase of the flux ratio is about 3% per minute to about 20% per minute and preferably about 10% per minute. In this embodiment, layer 414 comprises a region 414a of about 2-5 monolayers of substantially stoichiometric perovskite material and a region 414b of about 10-50 monolayers of graduated, non-stoichiometric perovskite material. It should be understood that the dashed line separating regions 414a and 414b in FIG. 4 has been inserted merely for clarity and convenience and is not intended to denote that regions 414a and 414b are distinct layers of structure 400, nor is it intended to indicate the relative thicknesses of regions 414a and 414b. Preferably, layer 414 comprises a region 414a of about 3-4 monolayers of substantially stoichiometric perovskite material and a region 414b of about 25-30 monolayers of graduated, non-stoichiometric perovskite material. In one aspect of this embodiment, layer 414 comprises a graduated, substantially stoichiometric to non-stoichiometric oxide having a thickness of less than or equal to about 15 nm and preferably about 10-15 nm.

In an exemplary embodiment, layer 414 comprises any suitable perovskite material, such as an alkaline-earth metal titanate, hafnate, zirconate, tantalate, vanadate, ruthenate, niobate, and/or the like. For example, in the case of strontium titanate, epitaxy may begin with a substantially stoichiometric Sr/Ti flux ratio (i.e. about 1:1), which is gradually increased or ramped-up to an ending flux ratio of about 2:1 of non-stoichiometric Sr₁₊ₓTiO₃₊ₓ (where x is greater than 0) within monocrystalline oxide layer 414. In this embodiment, oxide growth by MBE is conducted at temperatures ranging from about 200 to about 800° C., and preferably about 400 to about 600° C. The partial pressure of oxygen is initially set at a minimum value, such as a value in the range of about (1-5)×10⁻⁷ mBar. The growth rate of the oxide layer is about 0.2-0.5 nm per minute. After initiating growth of the monocrystalline oxide layer, the partial pressure of oxygen is increased above the initial minimum value to a value in the range of about (0.5-5)×10⁻⁴ mBar. Similarly, in further exemplary embodiments, substantially stoichiometric barium titanate may be ramped-up from a Ba/Ti ratio of about 1:1 to form a region of graduated, non-stoichiometric Ba₁₊ₓTiO₃₊ₓ (where x is greater than 0), and substantially stoichiometric barium strontium titanate may be ramped-up to form a region of graduated, non-stoichiometric (Sr_{z}Ba_{1-z})₁₊ₓTiO₃₊ₓ (where x is greater than 0 and z ranges from 0 to 1). A conductive gate electrode 416 is then formed on layer 414 in accordance with techniques well known to those skilled in the art to complete the structure of the MOS device.

In one embodiment of the present invention, layer 414 exhibits a substantially parabolic stoichiometry, as described above in greater detail with reference to layer 204 of FIG. 2A. In this embodiment, layer 414 is formed by incrementally varying the deposition flux ratio of the alkali metal or alkaline-earth metal to the transition metal from a substantially stoichiometric ration to non-stoichiometric ration and then back down to a substantially stoichiometric ratio.

In accordance with one aspect of the present invention, an exemplary process for fabricating a semiconductor device structure may comprise one or more of the following steps: establishing an independently selected first flux ratio for the elemental components comprising the perovskite material; depositing from about 1-5 monolayers (preferably about 2-4 monolayers) of the perovskite material using this first flux ratio; establishing an independently selected second flux ratio for the elemental components of the perovskite material; depositing from about 1-5 monolayers (preferably about 2-4 monolayers) of the perovskite material using the second flux ratio; establishing independently selected n^{th} flux ratio for the elemental components of the perovskite material; depositing from about 1-5 monolayers (preferably about 2-4 monolayers) of the perovskite material using the n^{th} flux ratio; repeating the steps of establishing an n^{th} flux ratio and depositing the perovskite material with the n^{th} flux ratio until a target flux ratio is achieved; and depositing from about 1-10 monolayers (preferably about 3-5 monolayers) of the perovskite material using this target flux ratio.

In one embodiment, as shown schematically in FIG. 6, the target flux ratio may be a ratio of alkali metal or alkaline-earth metal to transition metal of from about 1.1:1 to about 2.2:1 and preferably is about 2:1. It should be understood that FIG. 6 is not drawn to scale and is intended as a general, non-quantitative illustration of aspects of the invention. Thus, FIG. 6 is not intended to represent relative quantities, relative rates, relative periods of time, or any other variable or non-variable data which may otherwise be derived from such an illustration.

As used herein, the phrase “n^{th} flux ratio” encompasses any number of different flux ratios that may be established during the process of achieving a target flux ratio for the elemental components of the perovskite material. Accordingly, an (n−1)^{th} flux ratio is a penultimate flux ratio established during a process, regardless of the total number of flux ratios established during any particular process. For example, if a given process includes establishing five flux ratio steps for the elemental components of the perovskite material, the n^{th} flux ratio is the fifth flux ratio, and the (n−1)^{th} flux ratio is the fourth flux ratio.

In an alternate embodiment of this process, once a target non-stoichiometric flux ratio is achieved and about 1-5 monolayers, preferably about 2-4 monolayers, have been deposited using this target flux ratio, the flux ratio is then incrementally decreased until a substantially stoichiometric ratio is once again achieved. As one skilled in the art will appreciate, this may be accomplished by a process similar to the one described above, except that the flux ratio of the final step is substantially stoichiometric. In one embodiment, the process for returning to a substantially stoichiometric flux ratio from the target non-stoichiometric ratio comprises performing the above described process steps in a substantially reverse order, such that the (n−1)^{th} flux ratio is re-established after a suitable number of monolayers have been deposited using the n^{th} flux ratio, et cetera. In one embodiment, once a substantially stoichiometric ratio has been achieved, about 1-5 monolayers and preferably about 2-4 monolayers of substantially stoichiometric oxide material are deposited to complete the oxide layer.

In one embodiment, a constant flux rate is maintained for selected elemental components of the oxide while the flux rate of other elemental components is varied during the deposition process. In another embodiment, the flux rate of each elemental component is adjusted or varied over the course of the deposition process. In still another embodiment, variation or adjustment of a flux rate of an elemental component may comprise either gradually increasing the flux rate of that element toward a target flux rate or gradually decreasing the flux rate of that element toward a target flux rate.

Accordingly, the present invention provides a method for fabricating a high dielectric constant semiconductor device exhibiting reduced leakage current density as well as high crystallinity. As disclosed, various layers of the semiconductor device may be formed using a variety of deposition methods, including, but not limited to, molecular beam epitaxy (MBE), chemical beam epitaxy (CBE), metal-organic molecular beam epitaxy (MOMBE), ultra-high vacuum chemical vapor deposition (UHVCVD), physical vapor deposition (PVD), laser MBE, pulsed laser deposition (PLD), metal-organic chemical vapor deposition (MOCVD), and/or the like.

In the foregoing specification, the invention has been described with reference to specific embodiments. However, it will be appreciated that various modifications and changes can be made without departing from the scope of the present invention as set forth in the claims below. The specification and figures are to be regarded in an illustrative manner, rather than a restrictive one, and all such modifications are intended to be included within the scope of present invention. Accordingly, the scope of the invention should be determined by the appended claims and their legal equivalents, rather than by the examples given above. For example, the steps recited in any of the method or process claims may be executed in any order and are not limited to the order presented in the claims.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises”, “comprising”, or any other variation thereof, are intended to cover a non-exclusive inclusion, such that a process, method, article, or apparatus that comprises a list of elements does not include only those elements but may include other elements not expressly listed or inherent to such process, method, article, or apparatus. Further, no element described herein is required for the practice of the invention unless expressly described as “essential” or “critical”.

We claim:

1. A device structure comprising:
a monocrystalline material layer; and
a stoichiometrically graduated monocrystalline oxide layer overlying said monocrystalline material layer.

2. The device structure of claim 1, wherein said stoichiometrically graduated monocrystalline oxide layer comprises a perovskite material.

3. The device structure of claim 2, wherein said perovskite material comprises oxygen and at least one of one or more alkali metals, one or more alkaline earth metals, and one or more transition metals.

4. The device structure of claim 3, wherein said alkaline-earth metal comprises at least one of strontium and barium.

5. The device structure of claim 3, wherein said transition metal comprises at least one of titanium, zirconium, hafnium, tantalum, vanadium, ruthenium, niobium, and any lanthanide series element.

6. The device structure of claim 3, wherein a stoichiometrically graduated layer of said perovskite material comprises graduated ratios of alkali metal or alkaline earth metal to transition metal ranging from about 1:1 to about 2:1

7. The device structure of claim 3, wherein said perovskite material comprises a material selected from the group consisting of strontium titanate, barium titanate, and strontium barium titanate.

8. The device structure of claim 1, wherein said monocrystalline material layer is a monocrystalline semiconductor substrate comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

9. The device structure of claim 1, wherein said stoichiometrically graduated monocrystalline oxide layer comprises a first region of substantially stoichiometric oxide material and a second region of graduated, non-stoichiometric oxide material.

10. The device structure of claim 9, wherein said first region comprises a perovskite material having a ratio of alkali metal or alkaline-earth metal to transition metal of about 1:1.

11. The device structure of claim 10, wherein said second region comprises a perovskite material having graduated ratios of alkali metal or alkaline-earth metal to transition metal greater than 1:1.

12. The device structure of claim 11, wherein said graduated ratios of alkali metal or alkaline-earth metal to transition metal of said second region are less than or equal to about 2:1.

13. The device structure of claim 9, wherein said first region and said second region comprise a combined thickness of about 10-15 nm.

14. The device structure of claim 9, wherein said first region comprises about 2-5 monolayers of said substantially stoichiometric oxide material and said second region comprises about 10-30 monolayers of said graduated, non-stoichiometric oxide material.

15. The device structure of claim 1, further comprising an additional monocrystalline material layer overlying said stoichiometrically graduated monocrystalline oxide layer.

16. The device structure of claim 15, wherein said additional monocrystalline material layer is a monocrystalline semiconductor comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

17. The device structure of claim 1, wherein said stoichiometrically graduated monocrystalline oxide layer forms a gate dielectric.

18. The device structure of claim 17, further comprising a conductive gate electrode overlying said gate dielectric.

19. The device structure of claim 1, further comprising an amorphous interfacial layer overlying said monocrystalline material layer and underlying said stoichiometrically graduated monocrystalline oxide layer.

20. The device structure of claim 19, wherein said amorphous interfacial layer comprises silicon oxide.

21. The device structure of claim 1, wherein said stoichiometrically graduated monocrystalline oxide layer comprises a substantially parabolic stoichiometry.

22. The device structure of claim 21, wherein said substantially parabolic stoichiometry comprises a first region of substantially stoichiometric oxide material underlying a second region of non-stoichiometric oxide material which underlies a third region of substantially stoichiometric oxide material.

23. The device structure of claim 22, wherein said first, second, and third regions comprise a combined thickness of about 10-15 nm.

24. The device structure of claim 22, wherein said first region comprises a perovskite material having a ratio of alkali metal or alkaline-earth metal to transition metal of about 1:1.

25. The device structure of claim 24, wherein said second region comprises a perovskite material having graduated ratios of alkali metal or alkaline-earth metal to transition metal greater than 1:1.

26. The device structure of claim 25, wherein said second region comprises a perovskite material having graduated ratios of alkali metal or alkaline-earth metal to transition metal less than or equal to about 2:1.

27. The device structure of claim 26, wherein said third region comprises a perovskite material having a ratio of alkali metal or alkaline-earth metal to transition metal of about 1:1.

28. A semiconductor device structure comprising:
a monocrystalline material layer;
a monocrystalline oxide layer overlying said monocrystalline material layer; and
a stoichiometrically graduated monocrystalline oxide layer overlying said monocrystalline oxide layer.

29. The device structure of claim 28, wherein said monocrystalline oxide layer is substantially stoichiometric and said stoichiometrically graduated monocrystalline oxide layer is non-stoichiometric.

30. The device structure of claim 29, wherein said monocrystalline oxide layer and said stoichiometrically graduated monocrystalline oxide layer each comprises an independently selected perovskite material.

31. The device structure of claim 30, wherein said independently selected perovskite material comprises oxygen and at least one of one or more alkali metals, one or more alkaline-earth metals, and one or more transition metals.

32. The device structure of claim 31, wherein said stoichiometrically graduated monocrystalline oxide comprises a perovskite material comprising graduated ratios of alkali metal or alkaline-earth metal to transition metal, wherein each ratio is less than or equal to about 2:1.

33. The device structure of claim 31, wherein said alkaline-earth metal comprises at least one of strontium and barium.

34. The device structure of claim 31, wherein said transition metal comprises at least one of titanium, zirconium, hafnium, tantalum, vanadium, ruthenium, niobium, and any lanthanide series element.

35. The device structure of claim 31, wherein said independently selected perovskite material comprises a material selected from the group consisting of strontium titanate, barium titanate, and strontium barium titanate.

36. The device structure of claim 28, wherein said monocrystalline material layer comprises a monocrystalline semiconductor substrate comprising a material selected from the group consisting of silicon, germanium, silicon germanium, silicon carbide, indium phosphide, gallium arsenide, indium gallium arsenide, indium aluminum arsenide, aluminum gallium arsenide, and indium gallium phosphide.

37. The device structure of claim 28, further comprising an additional monocrystalline material layer overlying said stoichiometrically graduated monocrystalline oxide layer.

38. The device structure of claim 37, wherein said additional monocrystalline material layer comprises a monocrystalline semiconductor comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

39. The device structure of claim 28, wherein said monocrystalline oxide layer and said stoichiometrically graduated monocrystalline oxide layer collectively form a gate dielectric.

40. The device structure of claim 39, further comprising a conductive gate electrode formed on said gate dielectric.

41. The device structure of claim 28, wherein said stoichiometrically graduated monocrystalline oxide layer comprises a material selected from the group consisting of strontium titanate, barium titanate, and strontium barium titanate.

42. The device structure of claim 28, further comprising an amorphous interfacial layer overlying said monocrystalline material layer and underlying said monocrystalline oxide layer.

43. The device structure of claim 42, wherein said amorphous interfacial layer comprises silicon oxide.

44. The device structure of claim 28, wherein said stoichiometrically graduated monocrystalline oxide layer comprises a first region of non-stoichiometric oxide material underlying a second region of substantially stoichiometric oxide material.

45. The device structure of claim 44, wherein said first and second regions comprise a combined thickness of about 10-15 nm.

46. The device structure of claim 44, wherein said first region comprises a perovskite material having graduated ratios of alkali metal or alkaline-earth metal to transition metal greater than 1:1.

47. The device structure of claim 46, wherein said first region comprises a perovskite material having graduated ratios of alkali metal or alkaline-earth metal to transition metal less than or equal to about 2:1.

48. The device structure of claim 47, wherein said second region comprises a perovskite material having a ratio of alkali metal or alkaline-earth metal to transition metal of about 1:1.

49. A semiconductor device structure comprising:
a monocrystalline semiconductor substrate;
spaced apart source and drain regions formed in said substrate and defining a channel region there between;
a stoichiometrically graduated monocrystalline oxide layer overlying said channel region; and
a conductive gate electrode overlying said stoichiometrically graduated monocrystalline oxide layer and said channel region.

50. The semiconductor device structure of claim 49, wherein said monocrystalline semiconductor substrate comprises a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

51. The semiconductor device structure of claim 49, wherein said monocrystalline semiconductor substrate comprises a monocrystalline compound semiconductor material selected from the group consisting of gallium arsenide, indium gallium arsenide, indium aluminum arsenide, aluminum gallium arsenide, and indium gallium phosphide, and wherein said monocrystalline semiconductor substrate overlies a bulk monocrystalline substrate comprising material selected from the group consisting of silicon, germanium, silicon germanium, gallium arsenide, indium phosphide, and silicon carbide.

52. The device structure of claim 49, wherein said stoichiometrically graduated monocrystalline oxide layer comprises a perovskite material.

53. The device structure of claim 52, wherein said perovskite material comprises oxygen and at least one of one or more alkali metals, one or more alkaline earth metals, and one or more transition metals.

54. The device structure of claim 53, wherein said alkaline-earth metal comprises at least one of strontium and barium.

55. The device structure of claim 53, wherein said transition metal comprises at least one of titanium, zirconium, hafnium, tantalum, vanadium, ruthenium, niobium, and any lanthanide series element.

56. The device structure of claim 53, wherein said perovskite material comprises graduated ratios of alkali metal or alkaline-earth metal to transition metal ranging from about 1:1 to about 2:1.

57. The device structure of claim 53, wherein said perovskite material comprises a material selected from the group consisting of strontium titanate, barium titanate, and strontium barium titanate.

58. The device structure of claim 49, wherein said stoichiometrically graduated monocrystalline oxide layer comprises a first region of substantially stoichiometric oxide material and a second region of graduated, non-stoichiometric oxide material.

59. The device structure of claim 58, wherein said first region comprises a perovskite material having a ratio of alkali metal or alkaline-earth metal to transition metal of about 1:1.

60. The device structure of claim 59, wherein said second region comprises a perovskite material comprising graduated ratios of alkali metal or alkaline-earth metal to transition metal, wherein each ratio is greater than 1:1.

61. The device structure of claim 60, wherein said ratios of alkali metal or alkaline-earth metal to transition metal of said second region are less than or equal to about 2:1.

62. The device structure of claim 58, wherein said first region and said second region comprise a combined thickness of about 10-15 nm.

63. The device structure of claim 58, wherein said first region comprises about 2-5 monolayers of said substantially stoichiometric oxide material and said second region comprises about 10-30 monolayers of said graduated, non-stoichiometric oxide material.

64. The device structure of claim 49, further comprising an additional monocrystalline oxide layer overlying said monocrystalline semiconductor substrate and underlying said stoichiometrically graduated monocrystalline oxide material.

65. The device structure of claim 64, further comprising a semiconductor material or compound semiconductor material overlying said additional monocrystalline oxide layer and underlying said stoichiometrically graduated monocrystalline oxide material.

66. The device structure of claim 57, further comprising an additional monocrystalline oxide layer overlying said monocrystalline semiconductor substrate and underlying said stoichiometrically graduated monocrystalline oxide material.

67. The device structure of claim 66, further comprising a semiconductor material or compound semiconductor material overlying said additional monocrystalline oxide layer and underlying said stoichiometrically graduated monocrystalline oxide material.

68. The device structure of claim 61, further comprising an additional monocrystalline oxide layer overlying said monocrystalline semiconductor substrate and underlying said stoichiometrically graduated monocrystalline oxide material.

69. The device structure of claim 68, further comprising a semiconductor material or compound semiconductor material overlying said additional monocrystalline oxide layer and underlying said stoichiometrically graduated monocrystalline oxide material.

70. The device structure of claim 49, further comprising an amorphous interfacial layer overlying said monocrystalline material layer and underlying said monocrystalline oxide layer.

71. The device structure of claim 70, wherein said amorphous interfacial layer comprises silicon oxide.

72. The device structure of claim 49, wherein said stoichiometrically graduated monocrystalline oxide layer comprises a substantially parabolic stoichiometry.

73. The device structure of claim 72, wherein said substantially parabolic stoichiometry comprises a first region of substantially stoichiometric oxide material underlying a second region of non-stoichiometric oxide material which underlies a third region of substantially stoichiometric oxide material.

74. The device structure of claim 73, wherein said first, second, and third regions comprise a combined thickness of about 10-15 nm.

75. The device structure of claim 73, wherein said first region comprises a perovskite material having a ratio of alkali metal or alkaline-earth metal to transition metal of about 1:1.

76. The device structure of claim 75, wherein said second region comprises a perovskite material having graduated ratios of alkali metal or alkaline-earth metal to transition metal greater than 1:1.

77. The device structure of claim 76, wherein said second region comprises a perovskite material having graduated ratios of alkali metal or alkaline-earth metal to transition metal less than or equal to about 2:1.

78. The device structure of claim 77, wherein said third region comprises a perovskite material having a ratio of alkali metal or alkaline-earth metal to transition metal of about 1:1.

79. A semiconductor device structure comprising:
a monocrystalline material layer;
a monocrystalline oxide layer overlying said monocrystalline material layer, wherein said monocrystalline oxide layer is configured to exhibit a high degree of crystallinity and reduced leakage current density.

80. The device structure of claim 79, wherein said monocrystalline oxide layer comprises a perovskite material.

81. The device structure of claim 80, wherein said perovskite material comprises oxygen and at least one of one or more alkali metals, one or more alkaline earth metals, and one or more transition metals.

82. The device structure of claim 81, wherein said alkaline-earth metal comprises at least one of strontium and barium.

83. The device structure of claim 81, wherein said transition metal comprises at least one of titanium, zirconium, hafnium, tantalum, vanadium, ruthenium, niobium, and any lanthanide series element.

84. The device structure of claim 81, wherein said monocrystalline oxide layer comprises a stoichiometrically graduated layer of said perovskite material, and wherein said stoichiometrically graduated layer comprises graduated ratios of alkali metal or alkaline-earth metal to transition metal ranging from about 1:1 to about 2:1.

85. The device structure of claim 81, wherein said stoichiometrically graduated layer of said perovskite material comprises a substantially parabolic stoichiometry, wherein said graduated ratios of alkali metal or alkaline-earth metal to transition metal range from about 1:1 to about 2:1 and then back to about 1:1.

86. The device structure of claim 81, wherein said perovskite material comprises a material selected from the group consisting of strontium titanate, barium titanate, and strontium barium titanate.

87. The device structure of claim 79, wherein said monocrystalline material layer is a monocrystalline semiconductor substrate comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

88. The device structure of claim 79, further comprising an additional monocrystalline material layer overlying said monocrystalline oxide layer.

89. The device structure of claim 88, wherein said additional monocrystalline material layer is a monocrystalline semiconductor substrate comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

90. The device structure of claim 79, wherein said monocrystalline oxide layer forms a gate dielectric.

91. The device structure of claim 90, further comprising a conductive gate electrode overlying said gate dielectric.

92. The device structure of claim 79, further comprising an amorphous interfacial layer overlying said monocrystalline material layer and underlying said monocrystalline oxide layer.

93. The device structure of claim 92, wherein said amorphous interfacial layer comprises silicon oxide.

94. A process for fabricating a semiconductor device structure comprising:
providing a monocrystalline material layer;
depositing a stoichiometrically graduated monocrystalline oxide layer overlying said monocrystalline material layer.

95. The process of claim 94, wherein the step of providing a monocrystalline material layer comprises providing a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

96. The process of claim 94, wherein the step of providing a monocrystalline material layer comprises providing a monocrystalline semiconductor substrate.

97. The process of claim 96, wherein the step of providing a monocrystalline semiconductor substrate comprises providing a substrate comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

98. The process of claim 94, wherein the step of depositing comprises a process selected from the group consisting of molecular beam epitaxy, chemical vapor deposition, chemical beam epitaxy, metal organic chemical vapor deposition, metal organic molecular beam epitaxy, ultra-high vacuum chemical vapor deposition, migration enhanced epitaxy, atomic layer epitaxy, physical vapor deposition, chemical solution deposition, laser molecular beam epitaxy, and pulsed laser deposition.

99. The process of claim 94, wherein the step of depositing comprises adjusting a deposition flux ratio from a substantially stoichiometric ratio to a non-stoichiometric ratio.

100. The process of claim 94, wherein the step of depositing comprises adjusting a deposition flux ratio of alkali metal or alkaline-earth metal to transition metal from a substantially stoichiometric ratio to a non-stoichiometric ratio and then back to a substantially stoichiometric ratio.

101. The process of claim 99, wherein the step of depositing further comprises depositing a perovskite material layer.

102. The process of claim 101, wherein the step of depositing a perovskite material layer further comprises depositing a perovskite material layer having graduated ratios of alkali metal or alkaline-earth metal to transition metal ranging from about 1:1 to about 2:1.

103. The process of claim 101, wherein the step of depositing a perovskite material layer further comprises depositing a perovskite material layer having graduated ratios of alkali metal or alkaline-earth metal to transition metal ranging from about 1:1 to about 2:1 and then back to about 1:1.

104. The process of claim 102, further comprising maintaining a constant flux rate of said alkali metal or alkaline-earth metal and varying a flux rate of said transition metal.

105. The process of claim 102, further comprising varying a flux rate of said alkali metal or alkaline-earth metal and maintaining a constant flux rate of said transition metal.

106. The process of claim 102, wherein the step of depositing a perovskite material layer further comprises depositing a material comprising oxygen and at least one of one or more alkali metals, one or more alkaline-earth metals, and one or more transition metals.

107. The process of claim 106, wherein said perovskite material comprises a material selected from the group consisting of alkaline-earth metal titanate, alkaline earth metal zirconate, alkaline-earth metal hafnate, alkaline-earth metal tantalate, alkaline-earth metal niobate, alkaline-earth metal vanadate, and alkaline-earth metal ruthenate.

108. The process of claim 107, wherein the step of depositing a perovskite material layer further comprises depositing a material selected from the group consisting of strontium titanate, barium titanate, and strontium barium titanate.

109. The process of claim 107, wherein depositing a perovskite material layer having graduated ratios of alkali metal or alkaline-earth metal to transition metal further comprises two or more of:
establishing an independently selected first flux ratio for elemental components of said perovskite material;
depositing from about 1-5 monolayers of said perovskite material using said first flux ratio;
establishing an independently selected second flux ratio for elemental components of said perovskite material;
depositing from about 1-5 monolayers of said perovskite material using said second flux ratio;
establishing independently selected n^{th} flux ratios for elemental components of said perovskite material until a target flux ratio is achieved;
depositing from about 1-5 monolayers of said perovskite material using each of said n^{th} flux ratios; and
depositing from about 1-10 monolayers of said perovskite material using said target flux ratio.

110. The process of claim 109, further comprising incrementally decreasing a flux ratio until a substantially stoichiometric ratio is achieved.

111. The process of claim 110, wherein the step of incrementally decreasing comprises performing the above steps in substantially reverse order.

112. The process of claim 110, further comprising depositing about 1-10 monolayers of substantially stoichiometric perovskite material.

113. The process of claim 109, wherein the steps of establishing a second flux ratio and establishing n^{th} flux ratios further comprise maintaining at least one first flux rate.

114. The process of claim 109, wherein establishing a second flux ratio further comprises establishing a second flux ratio different from said first flux ratio; and wherein establishing n^{th} flux ratios further comprises establishing an n^{th} flux ratio different from an (n−1)^{th} flux ratio.

115. The process of claim 94, further comprising growing an amorphous interfacial layer on said monocrystalline material layer at an interface between said monocrystalline material layer and said stoichiometrically graduated monocrystalline oxide layer.

116. The process of claim 115, wherein growing an amorphous interfacial layer comprises growing an amorphous interfacial layer comprising silicon oxide.

117. A process for fabricating a semiconductor device comprising the steps of:
providing a monocrystalline substrate having a substrate surface;
implanting at least one dopant to form spaced apart source and drain regions in said substrate surface;
epitaxially depositing a stoichiometrically graduated monocrystalline oxide layer overlying said substrate surface; and
forming a conductive electrode positioned between said source and drain regions and overlying said monocrystalline oxide layer.

118. The process of claim 117, wherein the step of providing a monocrystalline substrate comprises providing a substrate comprising a material selected from the group consisting of silicon, germanium, silicon carbide, indium phosphide, silicon germanium, gallium arsenide, indium gallium arsenide, indium aluminum arsenide, aluminum gallium arsenide, and indium gallium phosphide.

119. The process of claim 118, wherein the step of epitaxially depositing comprises a process selected from the group consisting of molecular beam epitaxy, chemical vapor deposition, metal organic chemical vapor deposition, migration enhanced epitaxy, atomic layer epitaxy, physical vapor deposition, chemical solution deposition, and pulsed laser deposition.

120. The process of claim 119, wherein the step of epitaxially depositing said stoichiometrically graduated monocrystalline oxide layer comprises depositing a perovskite material layer.

121. The process of claim 120, wherein said perovskite material comprises a material selected from the group consisting of alkaline-earth metal titanate, alkaline-earth metal zirconate, alkaline-earth metal hafnate, alkaline-earth metal tantalate, alkaline-earth metal niobate, alkaline-earth metal vanadate, and alkaline-earth metal ruthenate.

122. The process of claim 121, wherein the step of depositing a perovskite material layer further comprises depositing a material selected from the group consisting of strontium titanate, barium titanate, and strontium barium titanate.

123. The process of claim 119, wherein the step of epitaxially depositing further comprises adjusting a deposition flux ratio from a substantially stoichiometric ratio to a non-stoichiometric ratio.

124. The process of claim 119, wherein the step of epitaxially depositing further comprises adjusting a deposition flux ratio of alkali metal or alkaline-earth metal to transition metal from a substantially stoichiometric ratio to a non-stoichiometric ratio and then back to a substantially stoichiometric ratio.

125. The process of claim 123, wherein the step of epitaxially depositing further comprises depositing a perovskite material layer having graduated ratios of alkali metal or alkaline-earth metal to transition metal ranging from about 1:1 to about 2:1.

126. The process of claim 123, wherein the step of epitaxially depositing further comprises depositing a perovskite material layer having graduated ratios of alkali metal or alkaline-earth metal to transition metal ranging from about 1:1 to about 2:1 and then back to about 1:1.

127. The process of claim 119, further comprising growing an amorphous interfacial layer on said monocrystalline material layer at an interface between said monocrystalline material layer and said stoichiometrically graduated monocrystalline oxide layer.

128. The process of claim 127, wherein growing an amorphous interfacial layer comprises growing an amorphous interfacial layer comprising silicon oxide.

129. The process of claim 117 wherein the step of implanting at least one dopant comprises implanting a material selected from the group consisting of boron, aluminum, gallium, indium, phosphorus, arsenic, and antimony.
